(19) United States
(12) Patent Application Publication
(10) Pub. No.: US 2022/0178017 A1
(43) Pub. Date: Jun. 9, 2022

(54) CFX LAYER TO PROTECT ALUMINUM SURFACE FROM OVER-OXIDATION

(71) Applicant: Applied Materials, Inc., Santa Clara, CA (US)

(72) Inventors: Anup Kumar SINGH, Santa Clara, CA (US); Vinayak Vishwanath HASSAN, San Francisco, CA (US); Bhaskar KUMAR, San Jose, CA (US); Ganesh BALASUBRAMANIAN, Fremont, CA (US)

(21) Appl. No.: 17/110,785

(22) Filed: Dec. 3, 2020

(51) Int. Cl. C23C 16/26; H01L 21/02; C23C 16/505; C23C 16/455

(52) U.S. Cl. CPC C23C 16/26; C23C 16/45553; C23C 16/505; H01L 21/02376

(57) ABSTRACT

In one example, a method includes flowing a carbon-containing gas into a processing volume of a process chamber, the process chamber having internal surfaces comprising aluminum, and depositing a carbon film on the internal surfaces of the process chamber. The method also includes flowing fluorine radicals into the process chamber, and fluorinating the carbon film to create a CFₓ layer on the internal surfaces. The method also includes oxidizing the CFₓ layer on the internal surfaces creating an AlOCFₓ layer on the internal surfaces.

### BACKGROUND

### Field

Embodiments of the present disclosure generally relate to apparatus and methods utilized in the manufacture of semiconductor devices. More particularly, embodiments of the present disclosure relate to protective films for a substrate process chamber and methods of forming the same.

### Description of the Related Art

Integrated circuits have evolved into complex devices that can include millions of transistors, capacitors and resistors on a single chip. The evolution of chip designs continually involves faster circuitry and greater circuit density. The demands for faster circuits with greater circuit densities impose corresponding demands on the materials used to fabricate such integrated circuits. In particular, as the dimensions of integrated circuit components are reduced to the sub-micron scale, there is a trend to use low resistivity conductive materials as well as low dielectric constant insulating materials to obtain suitable electrical performance from such components.

The demands for greater integrated circuit densities also impose demands on the process sequences used in the manufacture of integrated circuit components. For example, when processing substrates, plasma cleaning a process chamber at either a high temperature or a high power cleans the process chamber at a decent rate. To increase throughput, the chamber can be cleaned at a high temperature or a high power, however, this may cause over-oxidation of aluminum chamber components. Over-oxidation of aluminum chamber components reduces the lifetime of chamber components. Over-oxidation of aluminum chamber components also causes defects in the resulting films.

Therefore, what is needed is an improved chamber cleaning process and protective layers for substrate process chambers.

### SUMMARY

The present disclosure generally relates to method of cleaning a process chamber and/or depositing protective films in a process chamber. In one embodiment, a method includes flowing a carbon-containing gas into a processing volume of a process chamber, the process chamber having internal surfaces comprising aluminum, and depositing a carbon film on the internal surfaces of the process chamber. The method also includes flowing fluorine radicals into the process chamber, and fluorinating the carbon film to create a CFₓ layer on the internal surfaces. The method also includes oxidizing the CFₓ layer on the internal surfaces creating a AlOCFₓ layer on the internal surfaces.

In another embodiment, a method comprises flowing a carbon-containing gas into a processing volume of a process chamber, wherein the process chamber includes internal surfaces comprising aluminum; depositing a carbon film on the internal surfaces; generating fluorine radicals in a remote plasma source and flowing the fluorine radicals into the processing volume for a time of about 5 minutes to about 10 minutes; fluorinating the carbon film and creating a CFₓ layer on the internal surfaces; exposing the CFₓ layer to first oxygen radicals; and oxidizing the CFₓ layer and creating a AlOCFₓ layer on the surface of the processing volume, wherein the thickness of the AlOCFₓ layer having a thickness greater than 100 Å.

In another embodiment, a method comprises flowing acetylene into a processing volume of a process chamber, the process chamber having internal surfaces comprising aluminum; depositing a carbon film on the internal surfaces; generating fluorine radicals in a remote plasma source from NF₃ and flowing the fluorine radicals into the processing volume; fluorinating the carbon film and creating a CFₓ layer on the internal surfaces; generating an oxygen plasma within the process chamber using RF power; and oxidizing the CFₓ layer on the internal surfaces creating a AlOCFₓ layer, wherein a thickness of the AlOCFₓ layer is about 100 Å to about 1000 Å.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross sectional view of a process chamber, according to one aspect of the disclosure.

FIG. 2 is a flowchart illustrating a method, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to a substrate process chamber utilized in substrate processing, and methods of forming a protective coating on internal surfaces of the substrate process chamber. Examples of process chambers and/or systems that may be adapted to benefit from exemplary aspects of the disclosure include the PIONEER™ PECVD system commercially available from Applied Materials, Inc., located in Santa Clara, Calif. It is contemplated that other process chambers and/or processing platforms, including those from other manufacturers, may be adapted to benefit from aspects of the disclosure.

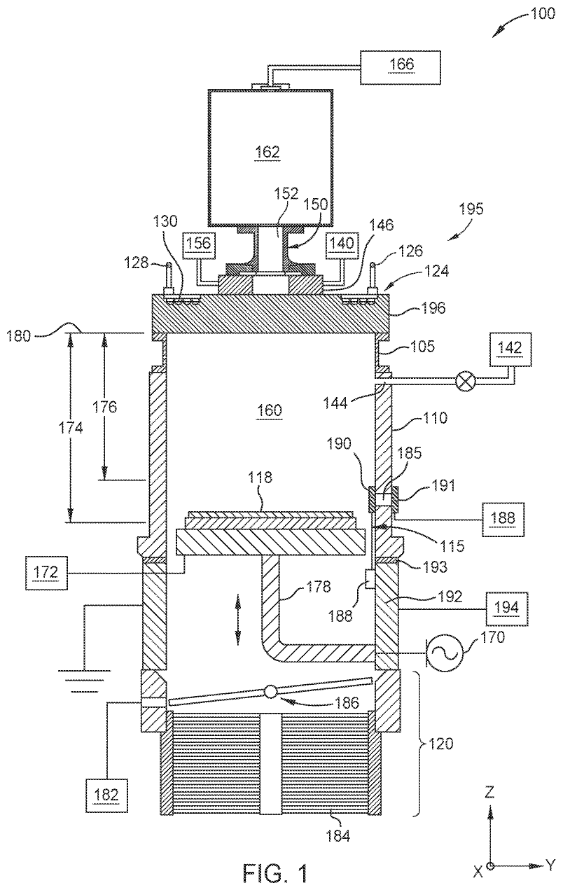

FIG. 1 is a schematic side cross sectional view of an illustrative process chamber 100 suitable for conducting a deposition process. In one embodiment, the process chamber 100 is configured to deposit advanced patterning films onto a substrate, such as hardmask films, for example amorphous carbon hardmask films. The process chamber 100 includes a lid 195, a spacer 110 disposed on a chamber body 192, a substrate support 115, and a variable pressure system 120. A processing volume 160 exists inside the spacer 110 between the lid 195 and the substrate support 115.

The lid 195 is coupled to a first process gas source 140. The first process gas source 140 contains a process gas, such as precursor gas for forming films on a substrate 118 supported on the substrate support 115. As an example, the precursor gas includes one or more of a carbon-containing precursor gas, such as acetylene (C₂H₂), a carrier gas, hydrogen gas, and/or helium among other gases.

A second process gas source 142 is fluidly coupled to the processing volume 160 via an inlet 144 disposed through the spacer 110. The second process gas source 142 contains a process gas, such as precursor gas, such as those specified above with respect to the first process gas source 140. In one example, the first process gas source 140 and the second process gas source 142 may be gas boxes, which each store and control the flow of multiple different gases to the processing volume 160.

In some embodiments, which may be combined with other embodiments, a total flow rate of precursor gas into the processing volume 160 is about 100 sccm to about 2 slm. A flow rate of precursor gas into the processing volume 160 from the second processing gas source 142 modulates a flow rate of precursor gas into the processing volume 160 from the first processing gas source 140 such that the combined precursor gas is uniformly distributed in the processing volume 160. In one example, a plurality of inlets 144 are distributed circumferentially about the spacer 110. In such an example, gas flow to each of the inlets 144 are separately controlled to further facilitate the uniform distribution of precursor gas within the processing volume 160.

The lid 195 includes a plate 196. The plate 196 is coupled to the spacer 110 via a riser 105, but it is contemplated that the riser 105 may be omitted and the plate 196 may be directly coupled to the spacer 110. In some embodiments, which may be combined with other embodiments, the riser 105 is integrated with the plate 196. The lid 195 includes a heat exchanger 124. The heat exchanger 124 is attached to the plate 196 or integrated with the plate 196. The heat exchanger 124 includes an inlet 126 and an outlet 128. In embodiments in which the heat exchanger 124 is integrated with the plate 196, heat exchange fluids flow from the inlet 126, through channels 130 formed in the plate 196, and out of the outlet 128. In one example, the plate 196 is a showerhead or other gas distributor.

The plate 196 is coupled to or integrated with a manifold 146. The plate 196 is coupled to a remote plasma source 162 by a conduit 150, such as a mixing ampoule, having an axial throughbore 152 to facilitate flow of plasma through the conduit 150. Although the conduit 150 is illustrated as coupled to the manifold 146, it is contemplated that the manifold 146 may be integrated with the conduit 150 such that the conduit 150 is directly coupled to the plate 196. The manifold 146 is coupled to the first process gas source 140 and a purge gas source 156. Both of the first process gas source 140 and the purge gas source 156 may be coupled to the manifold 146 by valves (not shown).

Although the lid 195 may be coupled to a remote plasma source 162, in some embodiments, the remote plasma source 162 is omitted. When present, the remote plasma source 162 is coupled to a cleaning gas source 166 via a feed line for providing cleaning gas to the processing volume 160. When the remote plasma source 162 is absent, the cleaning gas source 166 is directly coupled to the conduit 150. When the remote plasma source 162 is absent, the cleaning gas source 166 is indirectly coupled to the conduit 150. Cleaning gas is provided through the conduit 150. Additionally, or alternatively, in some embodiments, cleaning gas is provided through a channel that also conveys precursor gas into the processing volume 160. As an example, the cleaning gas may include one or more of: an oxygen-containing gas, such as molecular oxygen (O₂) and/or ozone (O₃), a fluorine-containing gas, such as NF₃, or other gases.

In addition to, or as an alternative to, the remote plasma source 162, the lid 195 is coupled to a first, or upper, radio frequency (RF) power source 168. The first RF power source 168 facilitates maintenance or generation of plasma, such as a plasma generated from a cleaning gas. In embodiments in which the remote plasma source 162 is omitted, the cleaning gas may be ionized into a plasma in situ via the first RF power source 168. The substrate support 115 may be coupled to a second, or lower, RF power source 170. The first RF power source 168 may be a high frequency RF power source (for example, about 13.56 MHz to about 120 MHz) and the second RF power source 170 may be a low frequency RF power source (for example, about 2 MHz to about 13.56 MHz). It is to be noted that other frequencies are also contemplated. In some implementations, the second RF power source 170 is a mixed frequency RF power source, providing both high frequency and low frequency power. Utilization of a dual frequency RF power source, particularly for the second RF power source 170, improves film deposition and increases the tunability of the film properties. In one example, a first frequency of about 2 MHz to about 13.56 MHz increases the ion bombardment to improve film properties, while a second frequency of about 13.56 MHz to about 120 MHz, such as about 40 MHz, increases ionization and deposition rate of the film.

One or both of the first RF power source 168 and the second RF power source 170 may be utilized in creating or maintaining a plasma in the processing volume 160. For example, the second RF power source 170 may be utilized during a deposition process, and the first RF power source 168 may be utilized during a cleaning process (alone or in conjunction with the remote plasma source 162). In some deposition processes, the first RF power source 168 is used in conjunction with the second RF power source 170. During a deposition process, one or both of the first RF power source 168 and the second RF power source 170 provide a power of about 100 Watts (W) to about 20,000 W, such as about 1,000 W to about 8,000W, to the processing volume 160 to facilitation ionization of a precursor gas. In one embodiment, which can be combined with other embodiments described herein, at least one of the first RF power source 168 and the second RF power source 170 are turned on or pulsed. In another embodiment, which can be combined with other embodiments described herein, the precursor gas includes helium, argon, and C₂H₂. In one embodiment, which can be combined with other embodiments described herein, C₂H₂ is provided at a flow rate of about 10 sccm to about 1,000 sccm and helium is provided at a flow rate of about 50 sccm to about 1,000 sccm.

The substrate support 115 is coupled to an actuator 172 (e.g., a lift actuator) that provides movement thereof in the Z direction. The substrate support 115 is also coupled to a facilities cable 178 that is flexible which allows vertical movement of the substrate support 115 while maintaining communication with the second RF power source 170 as well as other power and/or fluid connections. The spacer 110 is disposed on the chamber body 192. A height of the spacer 110 allows movement of the substrate support 115 vertically within the processing volume 160. The height of the spacer 110 may be from about 0.5 inches to about 20 inches. In one example, the substrate support 115 is movable from a first distance 174 to a second distance 176 relative to the lid 195 (for example, relative to a datum 180 of the plate 196). In one embodiment, the second distance 176 is about two-thirds of the first distance 174. For example, the difference between the first distance 174 and the second distance may be about 5 inches to about 6 inches. Thus, from the position shown in FIG. 1, the substrate support 115 is movable by about 5 inches to about 6 inches relative to a datum 180 of the plate 196. In another example, the substrate support 115 is fixed at one of the first distance 174 and the second distance 176. In one example, the distance 176 is about 2 inches to about 14 inches during a deposition process.

In contrast to conventional plasma enhanced chemical vapor deposition (PECVD) processes, the spacer 110 greatly increases the distance between (and thus the volume between) the substrate support 115 and the lid 195. The increased distance between the substrate support 115 and the lid 195 reduces collisions of ionized species in the process volume 160, resulting in deposition of film with less intrinsic stress, such as less than 300 megapascals (MPa), such as a stress of 250 MPa. Films deposited with less stress facilitate improved planarity (e.g., less bowing) of substrates upon which the film is formed. Reduced bowing of substrates results in improved precision of downstream lithography and patterning operations.

The variable pressure system 120 includes a first pump 182 and a second pump 184. The first pump 182 is a roughing pump that may be utilized during a cleaning process and/or substrate transfer process. A roughing pump is generally configured for moving higher volumetric flow rates and/or operating a relatively higher (though still sub-atmospheric) pressure. In one example, the first pump 182 maintains a pressure within the process chamber 100 less than 50 mTorr during a cleaning process. In another example, the first pump 182 is used for controlling a pressure within the process chamber 100 of about 0.5 mTorr to about 10 Torr, such as about 500 mTorr to about 10 Torr. Utilization of a roughing pump during cleaning operations facilitates relatively higher pressures and/or volumetric flow of cleaning gas (as compared to a deposition operation). The relatively higher pressure and/or volumetric flow during the cleaning operation improves cleaning of chamber surfaces.

The second pump 184 is a turbo pump or a cryogenic pump. The second pump 184 is utilized during a deposition process. The second pump 184 is generally configured to operate a relatively lower volumetric flow rate and/or pressure. For example, the second pump 184 is configured to maintain the processing volume 160 of the process chamber at a pressure of less than about 50 mTorr. In another example, the second pump 184 maintains a pressure within the process chamber of about 0.5 mTorr to about 10 Torr. The reduced pressure of the processing volume 160 maintained during deposition facilitates deposition of a film having reduced neutral stress and/or increased sp²-sp³ conversion, when depositing carbon-based hardmasks. Thus, process chamber 100 is configured to utilize both relatively lower pressure to improve film deposition properties and relatively higher and lower pressure to improve cleaning.

A valve 186 is utilized to control a conductance path to one or both of the first pump 182 and the second pump 184. The valve 186 also provides for symmetrical pumping from the processing volume 160.

The process chamber 100 also includes a substrate transfer port 185. The substrate transfer port 185 is selectively sealed by one or both of an interior door 190 and an exterior door 191. Each of the doors 190 and 191 are coupled to actuators 188 (i.e., a door actuator). The doors 190 and 191 facilitate vacuum sealing of the processing volume 160. The doors 190 and 191 also provide symmetrical RF application and/or plasma symmetry within the processing volume 160. In one example, at least the interior door 190 is formed of a material that facilitates conductance of RF power, such as stainless steel, aluminum, or alloys thereof. Seals 193, such as O-rings, disposed at the interface of the spacer 110 and the chamber body 192 may further seal the processing volume 160. A controller 194 is configured to control aspects of the process chamber 100 during processing. The control incudes hardware and software for executing one or more methods described herein.

In operation, the process chamber 100 is utilized to deposit amorphous carbon films onto substrates. High quality carbon is deposited onto the substrate due to the high RF application to the substrate support 115. The RF application results in high ion bombardment on the substrate causing the carbon to transition from sp² to sp³ on the substrate, and components adjacent the substrate, such as an insulating (e.g., aluminum oxide) ring of a process kit disposed on or adjacent a substrate support. As used herein, a “high quality film” refers to film that is free of stress induced failures, such as cracks, and includes a relatively high amount of sp³ carbon, such as a composition of greater than about 30% sp³ carbon. A low quality carbon is deposited on the walls of the processing volume 160 due to the walls being grounded. Carbon deposited on internal surfaces of the process chamber 100 may be referred to as “residue”.

After a predetermined number of deposition cycles, a cleaning process is performed in the processing volume. Conventional cleaning processes for carbon removal utilize oxygen to form volatile compounds which can be exhausted from the process chamber. In operation conventional operations, a plasma is formed in the remote plasma source resulting in a RPS cleaning process utilizing oxygen radicals. The resulting RPS cleaning process is utilized to clean the components of the processing volume, or the “low quality” carbon, such as activated carbon or graphitic carbon. However, the oxygen-based RPS cleaning is ineffective at removing the carbon deposited near the substrate support (e.g., the “high quality” carbon) or insulating ring due to the high RF bias on the substrate support, which facilitates deposition of the “high quality” carbon. To remove the “high quality” carbon, a capactively coupled plasma using an oxidant (such as oxygen or ozone) is generated using an RF top source, such as the RF source 168 shown in FIG. 1.

The RF oxygen radical clean is highly effective when cleaning the substrate support and surrounding areas. However, RF-generated oxygen plasmas can cause over-oxidation of the aluminum components of the process chamber. The over-oxidation results in a powdery film of aluminum oxide on the chamber surfaces that decreases adhesion of carbon to the process chamber surfaces which can flake off onto substrates during processing. Moreover, over-oxidation of aluminum components reduces the lifetime of the chamber parts, which are costly to replace. The over-oxidation of the process chamber results in defects and poor adhesion in resulting films. However, methods described herein provide improved resistance to the formation of aluminum oxide.

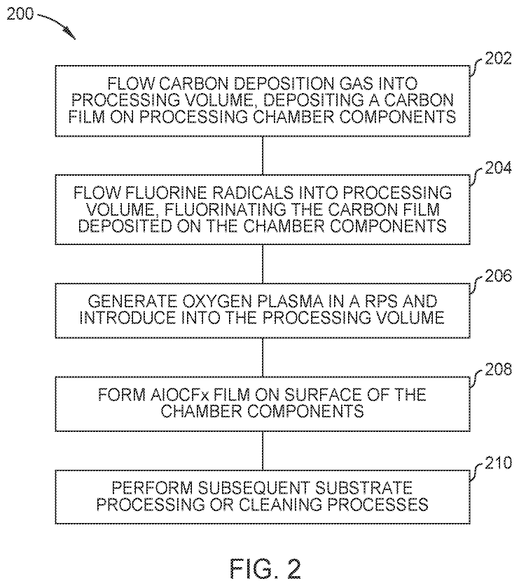

FIG. 2 is a flowchart illustrating a method 200 forming a protective layer on process chamber components. The protective layer increases the lifetime of chamber components and inhibits the formation of powdery aluminum oxide on chamber components. At operation 202, a carbon-containing gas, such as acetelyne (C₂H₂), is flowed into a process chamber in the presence of a substrate at a flow rate of about 100 sccm to about 2 slm, although other flow rates are contemplated. The pressure of the process chamber is between about 10 mTorr and about 100 mTorr. A high RF bias, such as about 100 W to about 20,000 W, such as about 1,000 W to about 4,000 W, is applied to the substrate support 115 by the RF power source 170 (See FIG. 1). The carbon film is deposited on the chamber components to a thickness of about 500 Å to about 2000 Å at a temperature that ranges from about 30° C. to about 200° C. Operation 202 may occur for at time period of about 5 minutes to about 10 minutes.

At operation 204, fluorine radicals are introduced into the processing volume 160, fluorinating the carbon film deposited on the walls of the processing volume 160. The fluorine radicals fluorinate the carbon film on and adjacent to the substrate support. However, the fluorinated film on/adjacent the substrate support is cleaned by subsequent applications of high RF bias oxygen plasma. The fluorine radicals are generated in a remote plasma source (RPS), such as the RPS 162, from a fluorine-containing gas, such as NF₃ or CF₄. The fluorine radicals are introduced in the presence of an optional carrier gas, such as argon or helium. While argon and helium are used as examples, it is contemplated that other carrier gases (such as process inert and/or noble gases) may be used in operation 204. Reaction of the fluorine radicals with the carbon deposited on aluminum (or aluminum alloy) chamber surfaces results in formation of a fluorinated carbon film (e.g., CFₓ; where x is a positive value) on/and or incorporating the aluminum (or aluminum alloy). The resulting fluorinated carbon film is highly resistant to oxidation by oxygen radicals, and functions as a protective film for the underlying aluminum chamber components, thus preventing over-oxidation of the aluminum chamber components which otherwise occurs in conventional cleaning processes. Operation 204 may occur for a time period of about 5 minutes to about 10 minutes. The fluorine radicals are introduced at a rate of about 100 sccm to about 500 sccm at a temperature that ranges from about 30° C. to about 200° C. The pressure of the processing volume is maintained at about 1 Torr.

At operation 206, oxygen radicals may be generated in situ via capacitively coupled plasma through application of RF power by the RF source 168. At operation 208, the oxygen plasma combines with the fluorinated carbon film on the internal aluminum surfaces of the process chamber 100. The film will be oxidized during the first RF cleaning process creating an AlOCFₓ film on the internal aluminum surfaces. The resulting AlOCFₓ film created on the surfaces protects the underlying aluminum components from over-oxidation. The resulting AlOCFₓ layer is about 1 Å to about 1000 Å thick, such as great than 100 Å, such as about 100 Å to about 1000 Å, such as 500 Å thick. Alternatively, direct formation of the AlOCFₓ is done by treatment of carbon film deposited in the chamber in the presence of RF oxygen plasma, such as O₂ plasma, and a fluorine-containing gas, such as NF₃ gas. In this embodiment, the flow rate of oxygen plasma is about 1,000 sccm and the flow rate of NF₃ is between about 50 sccm to about 100 sccm. The pressure of the chamber is between about 50 mTorr and about 500 mTorr.

The AlOCFₓ layer formed on the walls of the processing unit is generally removed only by high ion bombardment or mechanical removal. Since the walls of the processing volume are grounded (resulting in relative low ion bombardment), the AlOCFₓ layer is not removed by subsequent cleaning processes, such as RF-generated capacitively-coupled oxygen plasma. Therefore, the AlOCFₓ pretreatment layer protects the aluminum components from over-oxidation, increasing the longevity of the chamber.

At operation 210, subsequent processing or cleaning may occur in the process chamber. For example, in operation 210, a substrate is positioned in the process chamber, and carbon hardmask is formed on the substrate during a PECVD process. After a predetermined number of substrates are processed, the process chamber is subjected to a cleaning process. The cleaning process includes generating a capacitively coupled RF plasma, in situ, from diatomic oxygen or ozone, forming oxygen radicals. In this embodiment, the flow rate of oxygen plasma is about 1,000 sccm. The pressure of the chamber is between about 50 mTorr and about 500 mTorr. The temperature of the chamber components ranges from about 30° C. to about 200° C. The oxygen radicals react with carbon deposits on internal surfaces of the process chamber to form volatile compounds, which are exhausted from the process chamber. Due to the presence of the underlying AlOCFₓ, oxidation of the aluminum (or aluminum alloy) process chamber components is prevented, which reduces contamination with the process chamber and extends component useful life. Moreover, the capacitively coupled RF plasma facilitates removal of the high-quality, diamond-like carbon, which is difficult to remove using conventional approaches without generating contamination. After the cleaning process, additional substrates may be subjected to hardmask deposition processes within the process chamber.

Benefits of the disclosure included improved protective layers and improved cleaning of process chambers, for example those used for forming carbon hardmasks. Aspects of the disclosure are particularly beneficial for PECVD chambers having large volumes and/or process spacing, which results in carbon films have varying qualities being deposited in different locations throughout the process chamber. As noted above, the varying film qualities pose cleaning challenges. However, aspects of the disclosure simplify chamber cleaning while mitigating chamber component damage and contamination issues. Moreover, the protective layers disclosed herein exhibit significantly increased longevity compared to conventional seasoning layers, which often are reapplied after a predetermined number of cleanings. Because the protective layers disclosed herein do not require reapplication, process throughput is increased.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
flowing a carbon-containing gas into a processing volume of a process chamber, the process chamber having internal surfaces comprising aluminum;
depositing a carbon film on the internal surfaces of the process chamber;
flowing fluorine radicals into the process chamber;
fluorinating the carbon film to create a CFₓ layer on the internal surfaces; and
oxidizing the CFₓ layer on the internal surface creating a AlOCFₓ layer on the internal surface.

2. The method of claim 1, wherein the oxidizing the CFₓ layer comprising generating a capactively coupled plasma comprising oxygen radicals, using RF power.

3. The method of claim 1, wherein the carbon-containing gas is flowed at a flow rate of about 100 sccm to about 2 slm.

4. The method of claim 1, wherein oxidizing the CFₓ layer comprising generating a oxygen radicals in a remote plasma source, and introducing the oxygen radicals to the processing volume of the process chamber.

5. The method of claim 4, wherein the processing volume is exposed to the oxygen plasma for a time period within a range about 5 minutes to about 10 minutes, and exposed to the fluorine radicals for a time period within a range of about 5 minutes to about 10 minutes.

6. The method of claim 1, further comprising transferring a substrate into the processing volume, and forming a carbon hardmask on the substrate using acetylene as a carbon precursor.

7. The method of claim 6, wherein a distance between a showerhead of the process chamber and the substrate is about 2 inches to about 14 inches when forming the carbon hardmask on the substrate.

8. The method of claim 1, wherein the carbon film is deposited using acetylene as a carbon precursor.

9. The method of claim 8, wherein the acetylene is ionized by forming a capacitvely coupled plasma through application of RF power to a substrate support within the process chamber, the RF power provided within a range of about 1,500 W to about 6,000 W.

10. The method of claim 1, wherein a resulting thickness of the AlOCFₓ layer is about 100 Å to about 1000 Å.

11. The method of claim 1, wherein oxidizing the CFₓ layer comprising generating a oxygen radicals in a remote plasma source, and introducing the oxygen radicals to the processing volume of the process chamber at a flow rate within a range of about 500 sccm to about 2,000 sccm.

12. A method, comprising:
flowing a carbon-containing gas into a processing volume of a process chamber, wherein the process chamber includes internal surfaces comprising aluminum;
depositing a carbon film on the internal surfaces;
generating fluorine radicals in a remote plasma source and flowing the fluorine radicals into the processing volume for a time of about 5 minutes to about 10 minutes;
fluorinating the carbon film and creating a CFₓ layer on the internal surfaces;
exposing the CFₓ layer to first oxygen radicals and/or ions; and
oxidizing the CFₓ layer and creating a AlOCFₓ layer on the internal surfaces, wherein the thickness of the AlOCFₓ layer is greater than 100 Å.

13. The method of claim 12, further comprising, after oxidizing the CFₓ layer, transferring a substrate into the process chamber and forming a carbon hardmask on the substrate, wherein formation of the carbon hardmask deposits carbon residue on the AlOCFₓ layer.

14. The method of claim 13, the carbon hardmask is deposited using acetylene as a carbon precursor.

15. The method of claim 14, wherein the acetylene is ionized by forming a capacitvely coupled plasma through application of RF power to a substrate support within the process chamber, the RF power provided within a range of about 1,500 W to about 6,000 W, and wherein a spacing between substrate and a showerhead of the process chamber is about 2 inches to about 14 inches.

16. The method of claim 15, further comprising generating a capactively coupled plasma comprising second oxygen radicals within the process chamber, using RF power, and contacting the carbon residue with the second oxygen radicals to form a volatile compound.

17. The method of claim 12, wherein the AlOCFₓ layer prevents oxidation of the internal surfaces comprising aluminum by the second oxygen radicals.

18. The method of claim 12, wherein the carbon-containing gas is flowed at a flow rate of about 100 sccm to about 2 slm.

19. A method, comprising:
flowing acetylene into a processing volume of a process chamber, the process chamber having internal surfaces comprising aluminum;
depositing a carbon film on the internal surfaces;
generating fluorine radicals in a remote plasma source from NF₃ and flowing the fluorine radicals into the processing volume;
fluorinating the carbon film and creating a CFₓ layer on the internal surfaces;
generating an oxygen plasma within the process chamber using RF power; and
oxidizing the CFₓ layer on the internal surfaces creating a AlOCFₓ layer, wherein a thickness of the AlOCFₓ layer is about 100 Å to about 1000 Å.

20. The method of claim 19, wherein the process chamber is maintained at a temperature of about 10° C. to about 200° C. and a pressure of about 10 mTorr to about 1,500 mTorr while forming the AlOCFₓ layer.
